(19) United States
(12) Patent Application Publication
(10) Pub. No.: US 2024/0321558 A1
(43) Pub. Date: Sep. 26, 2024

(54) SUBSTRATE PROCESSING APPARATUS, METHOD OF PROCESSING SUBSTRATE, METHOD OF MANUFACTURING SEMICONDUCTOR DEVICE AND RECORDING MEDIUM

(71) Applicant: Kokusai Electric Corporation, Tokyo (JP)

(72) Inventors: Takeshi YASUI, Toyama-shi (JP); Van Chieu Nguyen, Toyama-shi (JP)

(73) Assignee: Kokusai Electric Corporation, Tokyo (JP)

(21) Appl. No.: 18/612,398

(22) Filed: Mar. 21, 2024

(30) Foreign Application Priority Data
Mar. 24, 2023 (JP) 2023-049063

(51) Int. Cl. H01J 37/32; H01L 21/02

(52) U.S. Cl. CPC H01J 37/32513; H01J 37/32816; H01L 21/02164; H01L 21/02236; H01J 2237/2005; H01J 2237/24585

(57) ABSTRACT

There is provided a technique that includes: an upper container; a lower container provided below the upper container and constituting a processing chamber between the lower container and the upper container; a first seal portion disposed in a boundary region between the upper container and the lower container, the first seal portion including a first seal member and a second seal member; and a support that includes a support face disposed at a highest position below the upper container, is provided between the first seal member and the second seal member in a horizontal direction, and is made of a material harder than the first seal member and the second seal member.

### CROSS-REFERENCE TO RELATED APPLICATION

This application is based upon and claims the benefit of priority from Japanese Patent Application No. 2023-49063, filed on Mar. 24, 2023, the entire contents of which are incorporated herein by reference.

### FIELD

The present disclosure relates to a substrate processing apparatus, a method of processing a substrate, a method of manufacturing a semiconductor device, and a recording medium.

### DESCRIPTION OF THE RELATED ART

A substrate processing apparatus for processing a substrate is provided with a processing chamber for processing a substrate, and the processing chamber is sealed from the outside during substrate processing. A processing chamber is constituted by an upper container made of quartz and a lower container made of metal, and a flange portion provided at a lower portion of the upper container is pressed downward by a flange retainer and is supported by a support member. Then, a gap between the upper container and the lower container is sealed with a seal member.

### SUMMARY

Even if the space between the upper container and the lower container is sealed with the seal member as described above, the external gas may be mixed into the processing chamber.

An object of the present disclosure is to provide a technique for suppressing penetration of external gas into a processing chamber.

In one aspect of the present disclosure, there is provided a technique that includes:
an upper container;
a lower container provided below the upper container and constituting a processing chamber between the lower container and the upper container;
a first seal portion disposed in a boundary region between the upper container and the lower container, the first seal portion including a first seal member and a second seal member; and a support member that includes a support face disposed at a highest position below the upper container, is provided between the first seal member and the second seal member in a horizontal direction, and is made of a material harder than the first seal member and the second seal member.

### BRIEF DESCRIPTION OF THE DRAWINGS

FIG. 1 is a schematic configuration diagram of a substrate processing apparatus suitably used in one aspect of the present disclosure.

FIG. 2A is a cross-sectional view taken along line 2A-2A in FIG. 4 including a first seal portion and a second seal portion.

FIG. 2B is a cross-sectional view taken along line 2B-2B in FIG. 4 including the first seal portion and the second seal portion.

FIG. 3 is a cross-sectional view taken along line A-A in FIG. 2A.

FIG. 4 is a cross-sectional view taken along line B-B in FIG. 2A.

FIG. 5 is a cross-sectional view taken along line C-C in FIG. 2A.

FIG. 6 is a diagram showing a configuration of a controller of a substrate processing apparatus suitably used in one aspect of the present disclosure.

FIG. 7 is a flowchart showing a substrate processing step suitably used in one aspect of the present disclosure.

FIG. 8 is a flowchart of atmospheric pressure recovery processing.

FIG. 9 is a partial cross-sectional view including a first seal portion and a second seal portion according to a modified example of the present disclosure.

FIG. 10 is a schematic configuration diagram of a substrate processing apparatus suitably used in another aspect of the present disclosure.

### DETAILED DESCRIPTION

### <One Aspect of the Present Disclosure>

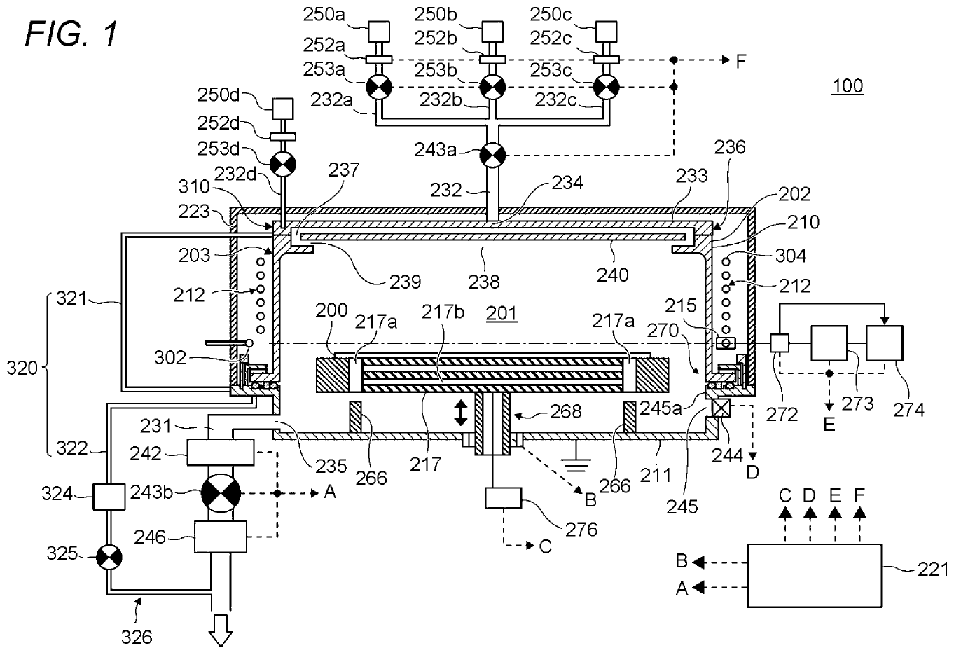

One aspect of the present disclosure will be described below with reference to FIGS. 1 to 8. Note that the drawings used in the following description are all schematic, and thus, dimensional relationships between constituent elements, ratios between constituent elements, and the like illustrated in the drawings do not necessarily coincide with realities. In addition, a plurality of drawings do not necessarily coincide with one another in dimensional relationships between constituent elements, ratios between constituent elements, and the like.

### (1) Configuration of Substrate Processing Apparatus

Next, a substrate processing apparatus 100 according to one aspect of the present disclosure will be described below with reference to FIG. 1. A substrate processing apparatus 100 according to one aspect of the present disclosure is configured to perform a modification treatment such as an oxidizing treatment or a nitriding treatment mainly on a film or a base formed on a substrate surface.

### (Processing Chamber)

The substrate processing apparatus 100 includes a processing furnace 202 that performs plasma processing on a wafer 200 serving as a substrate. The processing furnace 202 is provided with a processing container 203 constituting a processing chamber 201. The processing container 203 includes a cylindrical upper container 210 and a bowl-shaped lower container 211. When the upper container 210 covers the lower container 211, the processing chamber 201 is formed between the upper container 210 and the lower container 211. The upper container 210 is made of quartz. The upper container 210 constitutes a plasma container that forms a plasma generation space in which the processing gas is plasma-excited. The lower container 211 is made of metal.

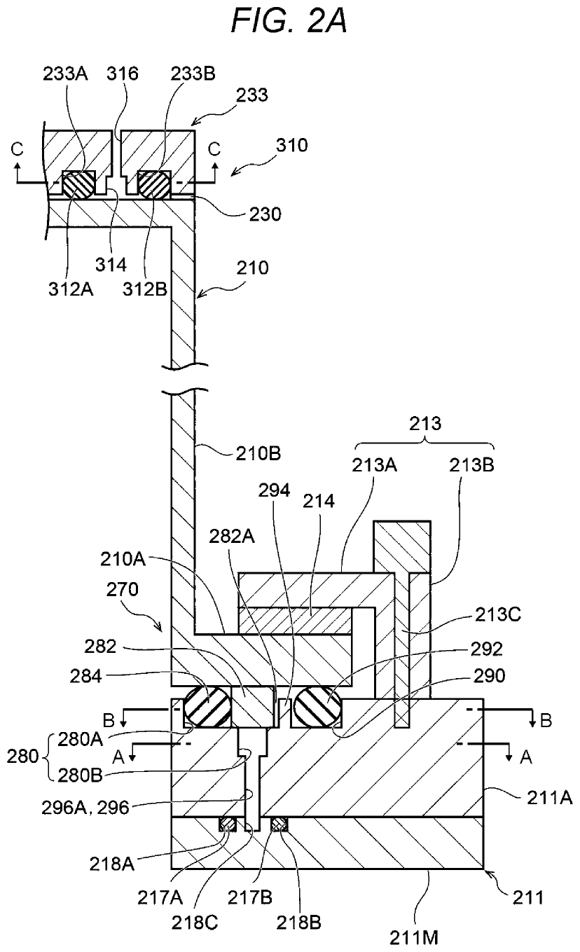

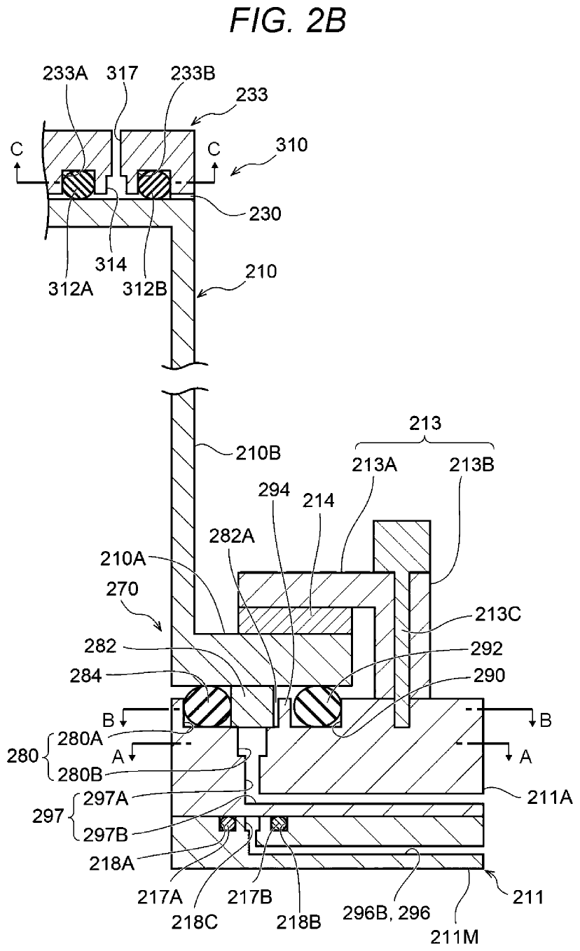

As illustrated in FIGS. 2A and 2B, the side wall of the upper container 210 has a peripheral wall 210B extending in the vertical direction and a flange 210A extending in the horizontal direction from the lower end of the peripheral wall 210B. An annular lower lid 211A is provided on an upper portion of the lower container 211. The lower lid 211A constitutes a part of the lower container 211, but is separated from the lower container body 211M. The first seal portion 270 is formed at a boundary portion (boundary region) between the flange 210A and the lower lid 211A. The first seal portion 270 has a configuration including a first seal member 284 and a second seal member 292 described later.

The flange 210A is provided with a ring-shaped flange retainer 213. The flange retainer 213 includes a retaining portion 213A having an inner diameter smaller than that of the flange 210A, and a side portion 213B provided outside the retaining portion 213A and protruding downward, the side portion 213B having an inner diameter larger than that of the flange 210A. A cushion material 214 is provided on a lower face of the retaining portion 213A. As the cushion material 214, Teflon (registered trademark) can be used as an example.

An upper face of the flange 210A is in contact with the flange retainer 213 via the cushion material 214, and the flange 210A and the flange retainer 213 are not in direct contact with each other. The flange retainer 213 is fastened to the lower lid 211A by a bolt 213C inserted into the through-hole of the side portion 213B.

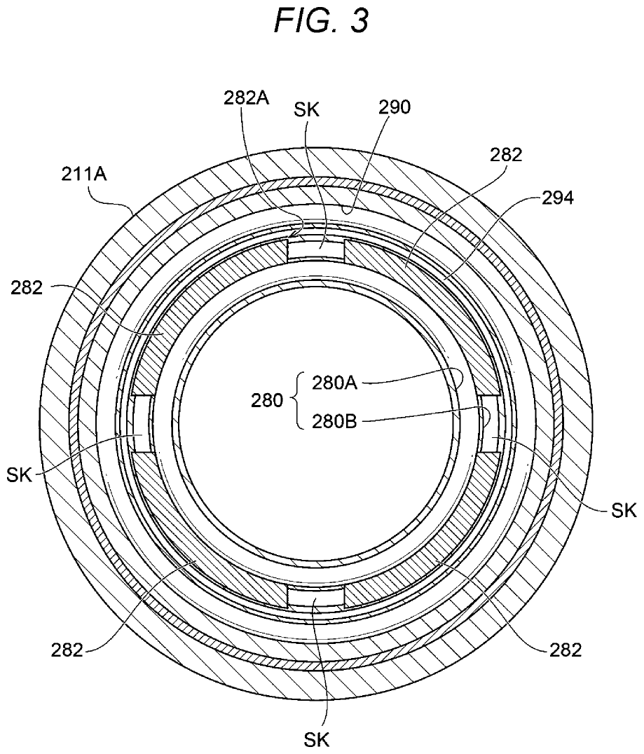

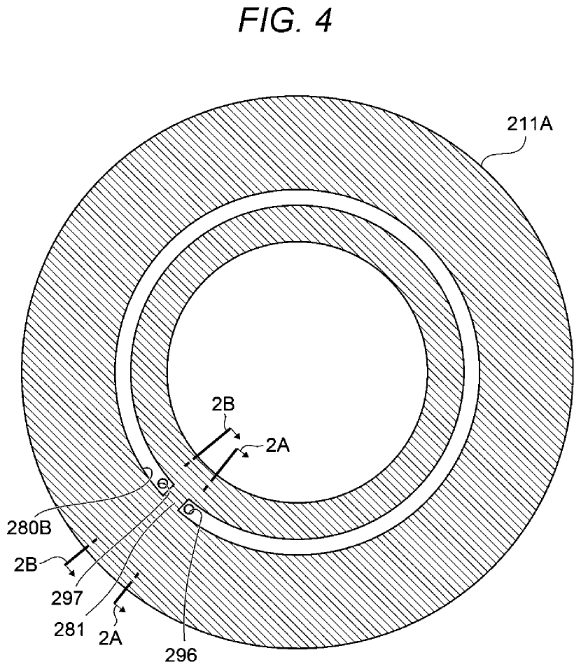

A first groove 280 is formed in the lower lid 211A of the lower container 211. As shown in FIG. 3, the first groove 280 is formed in an annular shape (circumferential shape), and includes an upper groove 280A and a lower groove 280B. In FIG. 3, illustration of the first seal member 284 and the second seal member 292 is omitted. The upper groove 280A is disposed on the upper face side of the lower lid 211A, and the lower groove 280B is narrower than the upper groove 280A and is formed with a step below the upper groove 280A. As illustrated in FIG. 4, a partition wall 281 is formed in the lower groove 280B. The partition wall 281 is formed to have a height flush with the bottom face of the upper groove 280A so as to fill a part of the lower groove 280B in the circumferential direction.

On the outer peripheral side of the first groove 280, a second groove 290 is formed concentrically with the first groove 280. That is, the first groove 280 is disposed on the central side of the upper container 210 with respect to the second groove 290 as viewed in the vertical direction. A partition wall 294 is formed between the first groove 280 and the second groove 290.

The support member 282 is disposed in the upper groove 280A of the first groove 280. The support member 282 is made of resin, and is made of a material such as polyimide or Vespel, for example. The support member 282 is made of a material harder than the first seal member 284 and the second seal member 292 described later. Here, “hard” means a property of being less likely to be deformed, and the support member 282 is formed of a material that is less likely to be elastically deformed than the first seal member 284 and the second seal member 292. The support member 282 is provided between the first seal member 284 and the second seal member 292 described later in the horizontal direction.

As illustrated in FIG. 3, the support member 282 is divided into a plurality of pieces (four pieces in the present embodiment) in the first groove 280, and the pieces are separated from each other in the circumferential direction to form the gap SK. As illustrated in FIG. 2A, the support member 282 has a quadrangular cross section, and is set to have a height larger than the depth of the upper groove 280A and a radial width larger than the groove width of the lower groove 280B. The support member 282 is disposed in the upper groove 280A so as to cover a part of the lower groove 280B. The support member 282 supports the flange 210A such that the upper face is in contact with the lower face of the flange 210A, the upper container 210 and the lower container 211 are separated from each other below the upper container 210, and are not in contact with each other. The support face on which the support member 282 supports the flange 210A is configured to be at the highest position below the flange 210A when viewed in the vertical direction.

In the upper groove 280A of the first groove 280, the first seal member 284 is disposed on the radially inner side (the central side of the upper container 210) with respect to the support member 282. The first seal member 284 is made of an elastic material such as rubber or elastomer. The first seal member 284 is configured such that, in a state of not being elastically deformed, an upper end thereof is above the support member 282 which is also not elastically deformed. By being sandwiched between the flange 210A and the lower lid 211A and receiving a pressing force, the first seal member 284 is elastically deformed and crushed, the support member 282 abuts on the lower face of the flange 210A, and the first seal member 284 seals a gap between the flange 210A and the lower lid 211A on the radially inner side of the support member 282.

The first seal member 284 is disposed with its radially outer side in contact with the support member 282. The support member 282 is disposed separately from an inner wall surface (a wall surface on the radially inner side of the partition wall 294) constituting the first groove 280 of the partition wall 294, and a gap 282A is formed in the circumferential direction. The gap 282A communicates with the gap SK.

The second seal member 292 is disposed in the second groove 290, and the first seal member 284 and the second seal member 292 are disposed horizontally inside and outside in the radial direction. The second seal member 292 is made of the same material as the first seal member 284. Similarly to the first seal member 284, the cross section of the second seal member 292 is configured such that the upper end is located above the support member 282 that is not elastically deformed. By being sandwiched between the flange 210A and the lower lid 211A and receiving a pressing force, the second seal member 292 is elastically deformed and crushed, the support member 282 abuts on the lower face of the flange 210A, and the second seal member 292 seals a gap between the flange 210A and the lower lid 211A on the radially outer side of the support member 282.

In a substrate processing step and the like described later, the hardness and the elastic modulus of the support member 282, the first seal member 284, and the second seal member 292 are set such that a space is secured between the flange 210A (upper container 210) and the lower lid 211A (lower container 211) even when the inside of the processing chamber 201 becomes vacuum and the pressure becomes lower than the pressure (atmospheric pressure) outside the processing chamber 201.

As illustrated in FIG. 4, in the lower lid 211A, a supply hole 297A communicating with the lower groove 280B is formed on one side across the partition wall 281, and a discharge hole 296A communicating with the lower groove 280B is formed on the other side across the partition wall 281. As shown in FIG. 2B, the supply hole 297A is pierced from the lower groove 280B in the thickness direction of the lower lid 211A in a non-penetrating manner, and communicates with the supply hole 297B pierced in the radial direction. The supply hole 297B extends radially outward from a position corresponding to the supply hole 297A and is formed over the radially outer end. The supply path 297 is formed by the supply hole 297A and the supply hole 297B.

As illustrated in FIG. 2A, the discharge hole 296A is drilled through the lower groove 280B in the thickness direction of the lower lid 211A, and communicates with a peripheral groove 218C formed in the lower container body 211M. The peripheral groove 218C is formed over substantially one turn from a position corresponding to the discharge hole 296A to a position corresponding to the supply hole 297A. The discharge hole 296A and the supply hole 297A are arranged on one side and the other side across a partition wall (not illustrated) provided at a position corresponding to the partition wall 281 of the lower lid 211A. As illustrated in FIG. 2B, the discharge hole 296B communicating with the peripheral groove 218C is formed at a position corresponding to the supply hole 297A in the circumferential direction in the lower container body 211M. The discharge hole 296A, the peripheral groove 218C, and the discharge hole 296B form a discharge path 296.

In the lower container main body 211M, a lower inner groove 218A and a lower outer groove 218B are annularly arranged over the entire circumference at a boundary face with the lower lid 211A. The lower inner groove 218A is disposed radially inside the peripheral groove 218C, and the lower outer groove 218B is disposed radially outside the peripheral groove 218C. A lower inner seal member 217A is disposed in the lower inner groove 218A, and a lower outer seal member 217B is disposed in the lower outer groove 218B. The supply path 297 is connected to a first intermediate flow path 321 to be described later, and the discharge path 296 is connected to a second intermediate flow path 322 to be described later. The supply path 297 and the discharge path 296 communicate with the space in the first groove 280.

As shown in FIG. 1, a gate valve 244 is provided on a lower side wall of the lower container 211. The gate valve 244 is configured to be able to load the wafer 200 into the processing chamber 201 or unload the wafer 200 out of the processing chamber 201 via a loading/unloading port 245 by using a transfer mechanism, when opened. The gate valve 244 is configured to be a gate valve for holding the airtightness in the processing chamber 201, when closed.

The processing chamber 201 includes a plasma generation space in which a resonance coil 212, which is a coil serving as an electrode, is provided around, and a substrate processing space serving as a substrate processing chamber that communicates with the plasma generation space and in which the wafer 200 is processed. The plasma generation space is a space in which plasma is generated, and is a space in the processing chamber 201 above the lower end of the resonance coil 212 and below the upper end of the resonance coil 212. On the other hand, the substrate processing space is a space in which the substrate is processed by using plasma and is a space below the lower end of the resonance coil 212. In one aspect of the present disclosure, the horizontal diameters of the plasma generation space and the substrate processing space are configured to be substantially the same as each other.

### (Susceptor)

A susceptor 217 serving as a substrate mount on which the wafer 200 is mounted is arranged at the bottom center of the processing chamber 201. The susceptor 217 is provided below the resonance coil 212 in the processing chamber 201.

A heater 217b serving as a heating mechanism is integrally embedded inside the susceptor 217. The heater 217b is configured to be able to heat the wafer 200 when power is supplied. The susceptor 217 is electrically insulated from the lower container 211.

The susceptor 217 is provided with a susceptor elevating mechanism 268 including a drive mechanism for moving up and down the susceptor 217. Furthermore, the susceptor 217 is provided with through-holes 217a, and wafer push-up pins 266 are provided on the bottom face of the lower container 211. The wafer push-up pins 266 are configured to penetrate through the through-holes 217a in a non-contact state with the susceptor 217 when the susceptor 217 is lowered by the susceptor elevating mechanism 268.

### (Gas Supplier)

A gas supply head 236 is provided above the processing chamber 201, that is, on the upper part of the upper container 210. The gas supply head 236 includes a cap-shaped lid 233, a gas inlet 234, a buffer chamber 237, an opening 238, a shielding plate 240, and a gas outlet 239, and is configured to be able to supply the reactant gas into the processing chamber 201. The buffer chamber 237 has a function as a dispersion space for dispersing the reactant gas introduced from the gas inlet 234.

A processing gas supply pipe 232 is provided such that the downstream end of an oxygen-containing gas supply pipe 232a for supplying an oxygen-containing gas, the downstream end of a hydrogen-containing gas supply pipe 232b for supplying a hydrogen-containing gas, and the downstream end of an inert gas supply pipe 232c for supplying an inert gas join together. The processing gas supply pipe 232 is connected to the lid 233 so as to communicate with the gas inlet 234. The oxygen-containing gas supply pipe 232a is provided with an oxygen-containing gas supply source 250a, a mass flow controller (MFC) 252a serving as a flow rate control apparatus, and a valve 253a serving as an on-off valve, in order from the upstream side. The hydrogen-containing gas supply pipe 232b is provided with a hydrogen-containing gas supply source 250b, an MFC 252b, and a valve 253b, in order from the upstream side. The inert gas supply pipe 232c is provided with an inert gas supply source 250c, an MFC 252c, and a valve 253c, in order from the upstream side. The processing gas supply pipe 232 is provided with a valve 243a and is connected to an upstream end of the gas inlet 234. The gas supply section is configured to be able to supply, into the processing chamber 201, processing gases such as the oxygen-containing gas, the hydrogen-containing gas, and the inert gas via the gas supply pipes 232a, 232b, and 232c while adjusting the flow rates of the respective gases by the MFCs 252a, 252b, and 252c, by opening and closing the valves 253a, 253b, 253c, and 243a.

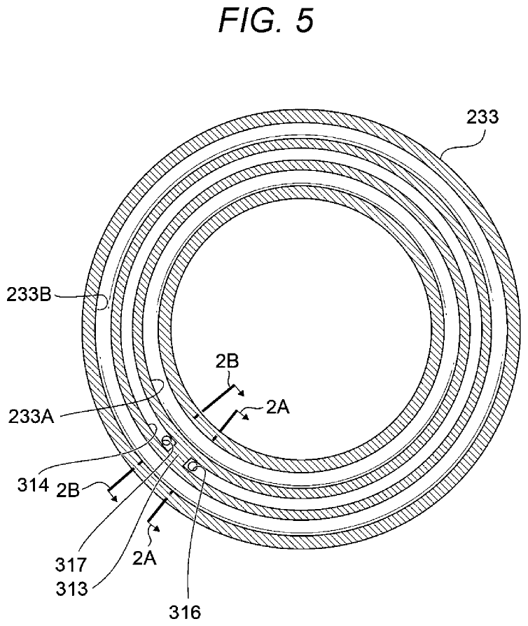

An opening 238 is formed in an upper portion of the upper container 210, and the opening 238 is covered with the lid 233. As illustrated in FIGS. 2A and 2B, a second seal portion 310 is annularly disposed at a boundary portion between the upper container 210 and the lid 233. Further, a support member 230 is provided between the lid 233 and the side wall 210. On the lower face of the lid 233 corresponding to the second seal portion 310, an inner groove 33A and an outer groove 233B are disposed over the entire circumference. An inner seal member 312A is disposed in the inner groove 233A, and an outer seal member 312B is disposed in the outer groove 233B. A lid groove 314 opened to the lower side of the lid 233 is formed between the inner groove 233A and the outer groove 233B. As illustrated in FIG. 5, a partition wall 313 is provided in a part of the lid groove 314 in the circumferential direction. The partition wall 313 is flush with the lower face of the lid 233.

In the lid 233, a supply hole 317 communicating with the lid groove 314 is formed on one side across the partition wall 313, and a discharge hole 316 serving as a second discharge path communicating with the lid groove 314 is formed on the other side across the partition wall 313. The supply hole 317 and the discharge hole 316 are formed to penetrate the lid 233. The supply hole 317 is connected to a second inert gas supply pipe 232d to be described later, and the discharge hole 316 is connected to a first intermediate flow path 321 to be described later.

The second inert gas supply pipe 232d is provided with a second inert gas supply source 250d, an MFC 252d, and a valve 253d in this order from the upstream side. By opening and closing the valve 253d, the inert gas can be supplied to the supply hole 317 via the second inert gas supply pipe 232d while the flow rate of the inert gas is adjusted by the MFC 252d.

### (Exhauster)

A gas exhaust port 235 for exhausting the reactant gas from the processing chamber 201 is provided on the side wall of the lower container 211. The upstream end of a gas exhaust pipe 231 serving as the gas discharge path is connected to the gas exhaust port 235. The gas exhaust pipe 231 is provided with an Auto Pressure Controller (APC) valve 242 serving as a pressure regulator (pressure regulating section), a valve 243b serving as an on-off valve, and a vacuum pump 246 serving as a vacuum-exhaust apparatus, in order from the upstream side.

### (Intermediate Flow Path)

The first intermediate flow path 321 and the lid 233 are connected such that the discharge hole 316 in the second seal portion 310 communicates with one end of the first intermediate flow path 321. The other end of the first intermediate flow path 321 is connected to the supply path 297 of the lower container 211. One end of the second intermediate flow path 322 is connected to the discharge path 296 of the lower container 211. The other end of the second intermediate flow path 322 is connected to the gas exhaust pipe 231 on the downstream side of the vacuum pump 246 (see FIG. 1). The first intermediate flow path 321 and the second intermediate flow path 322 constitute an intermediate flow path 320. From the second inert gas supply pipe 232d, the gas exhaust pipe 231, the supply hole 317, the lid groove 314, the discharge hole 316, the first intermediate flow path 321, the supply path 297, the first groove 280, the discharge path 296, and the second intermediate flow path 322 communicate in one stroke. The flow path from the supply hole 317 to the second intermediate flow path 322 is referred to as a seal-related flow path 326.

A pressure sensor 324 is provided in the second intermediate flow path 322. A valve 325 is provided on the downstream side of the pressure sensor 324.

### (Plasma Generator)

A resonance coil 212 is provided on an outer peripheral portion of the processing chamber 201, that is, on an outer side of a side wall of the upper container 210 so as to be spirally wound a plurality of times along an outer periphery of the upper container 210. The resonance coil 212 is connected to an RF sensor 272, a high-frequency power source 273, and a matching device 274 for performing matching of the impedance and output frequency of the high-frequency power source 273.

The high-frequency power source 273 supplies high-frequency power (RF power) to the resonance coil 212. The RF sensor 272 is provided on the output side of the high-frequency power source 273 and monitors information on a traveling wave and reflected wave of the high-frequency power supplied. The reflected wave power monitored by the RF sensor 272 is input to the matching device 274, and the matching device 274 controls the impedance of the high-frequency power source 273 and the frequency of the output high-frequency power so that the reflected wave is minimized, on the basis of information on the reflected wave input from the RF sensor 272.

The high-frequency power source 273 includes a power source control means (control circuit) including a high-frequency oscillation circuit and a preamplifier for defining the oscillation frequency and output, and an amplifier (output circuit) for performing amplification to a predetermined output. The power source control means controls the amplifier on the basis of output conditions regarding frequency and power set in advance through an operation panel. The amplifier supplies constant high-frequency power to the resonance coil 212 via a transmission line.

To form a standing wave having a predetermined wavelength, the winding diameter, the winding pitch, and the number of turns are set so that the resonance coil 212 resonate at a constant wavelength. That is, the electrical length of the resonance coil 212 is set to a length corresponding to an integral multiple (1x, 2x, . . . ) of one wavelength at a predetermined frequency of the high-frequency power supplied from the high-frequency power source 273.

Both ends of the resonance coil 212 are electrically grounded. One of both ends of the resonance coil 212 is grounded at a first grounding point 302 as a fixed ground. The other end of the resonance coil 212 is grounded at the second grounding point 304. The second grounding point 304 may be grounded via a movable tap in order to finely adjust the electrical length of the resonance coil. Furthermore, in order to finely adjust the impedance of the resonance coil 212 at the time of initial installation of the apparatus or change of the processing condition, a power supply is configured by a movable tap 215 between both grounded ends of the resonance coil 212. Further, the position of the movable tap 215 is adjusted so that the resonance characteristic of the resonance coil 212 is substantially equal to that of the high-frequency power source 273. Since the resonance coil 212 includes the variable grounding and the variable power supply, it is possible to more easily adjust the resonance frequency and the load impedance of the processing chamber 201 as described later.

The shielding plate 223 is provided to shield an electric field outside the resonance coil 212 and to generate a capacitance component (C component) necessary for forming a resonance circuit between the shielding plate and the resonance coil 212. The shielding plate 223 is generally formed in a cylindrical shape using a conductive material such as an aluminum alloy. The shielding plate 223 is disposed at a distance of about 5 to 150 mm from the outer periphery of the resonance coil 212.

### (Controller)

A controller 221 serving as the controller is configured to control: the APC valve 242, the valve 243b, and the vacuum pump 246, through a signal line A; the susceptor elevating mechanism 268 through a signal line B; a heater power adjusting mechanism 276, through a signal line C; the gate valve 244 through a signal line D; the RF sensor 272, the high-frequency power source 273, and the matching device 274, through a signal line E; and the MFCs 252a to 252d, and the valves 253a to 253d, 243a, and 325, and the pressure sensor 324 through a signal line F.

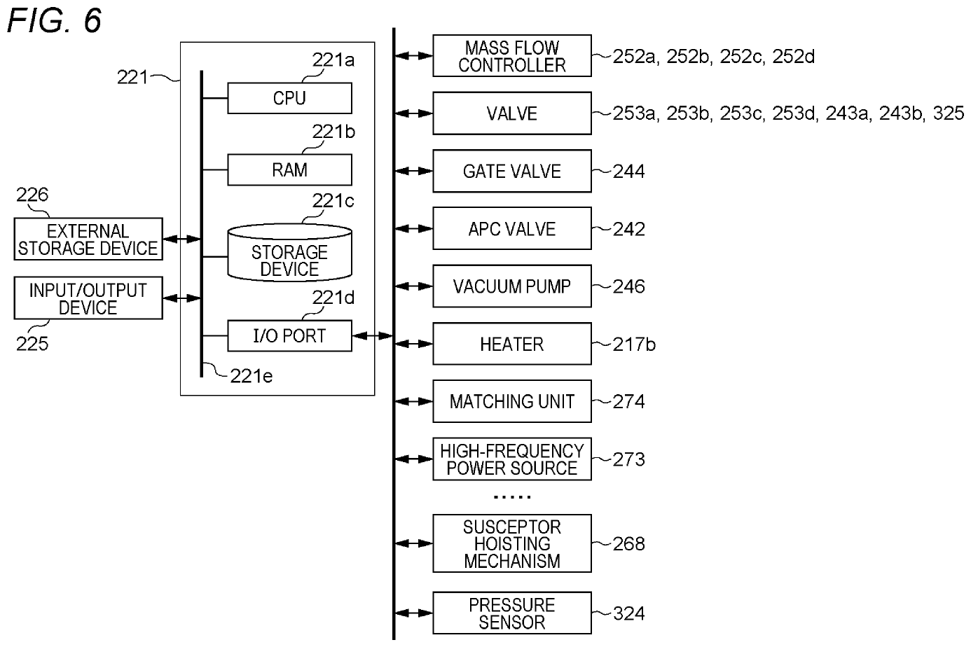

As illustrated in FIG. 6, the controller 221 serving as the controller (control means) is configured as a computer including a central processing unit (CPU) 221a, a random access memory (RAM) 221b, the storage device 221c, and an I/O port 221d. The RAM 221b, the storage device 221c, and the I/O port 221d are configured to be capable of exchanging data with the CPU 221a via an internal bus 221e. For example, an input/output device 225 configured as a touch panel or a display is connected to the controller 221.

The storage device 221c is configured by, for example, a flash memory, a Hard Disk Drive (HDD), or the like. In the storage device 221c, a control program for controlling operation of the substrate processing apparatus, a program recipe in which procedures and conditions of the substrate processing described later are described, and the like are readably stored. The process recipe is combined to cause the controller 221 to execute procedures in substrate processing step described later and obtain a predetermined result, and functions as a program. Hereinafter, the process recipe and the control program are also collectively and simply referred to as a program. Note that, when the term “program” is used in this specification, it may include a program recipe alone, may include a control program alone, or may include both. Furthermore, the RAM 221b is configured as a memory area (work area) in which programs, data, and the like read by the CPU 221a are temporarily held.

The I/O port 221d is connected to the above-described MFCs 252a to 252d, valves 253a to 253d, 243a, and 243b, gate valve 244, APC valve 242, vacuum pump 246, RF sensor 272, high-frequency power source 273, matching device 274, susceptor elevating mechanism 268, heater power adjusting mechanism 276, and the like.

The CPU 221a is configured to read and execute a control program from the storage device 221c, and to read a process recipe from the storage device 221c in response to input of an operation command from the input/output device 225, or the like. Then, the CPU 221a is configured to control: opening degree adjusting operation of the APC valve 242, opening/closing operation of the valve 243b, and start/stop of the vacuum pump 246, through the I/O port 221d and the signal line A; elevating operation of the susceptor elevating mechanism 268 through the signal line B; and supply power amount adjusting operation (temperature adjusting operation) to the heater 217b by the heater power adjusting mechanism 276, through the signal line C; opening/closing operation of the gate valve 244 through the signal line D; operations of the RF sensor 272, the matching device 274, and the high-frequency power source 273, through the signal line E; flow rate adjusting operation of various processing gases by the MFCs 252a to 252d, and opening/closing operation of the valves 253a to 253d, and 243a, through the signal line F; and the like in accordance with the details of the read process recipe.

The controller 221 can be configured by installing the above-described program stored in an external memory (for example, a magnetic tape, a magnetic disk such as a flexible disk or a hard disk, an optical disk such as a CD or a DVD, a magneto-optical disk such as an MO, or a semiconductor memory such as a USB memory or a memory card) 226 in a computer. The storage device 221c and the external memory 226 are configured as computer-readable recording media. Hereinafter, the memory 121c and the external memory 123 are also collectively and simply referred to as a recording medium. In this specification, a case where the term recording medium is used includes a case where the storage device 221c alone is included, a case where the external memory 226 alone is included, or a case where the both are included. The program may be provided to the computer not using the external memory 123 but using a communication means such as the Internet or a dedicated line.

### (2) Substrate Processing Step

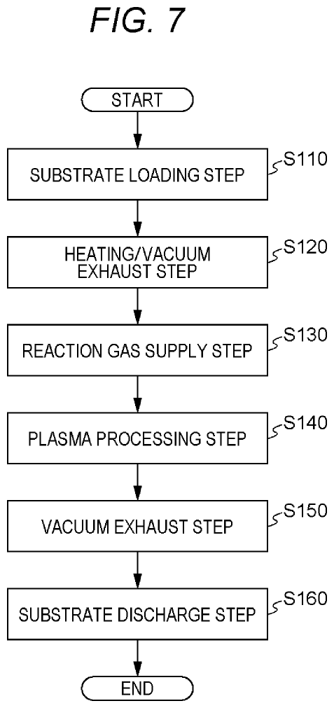

Next, a substrate processing step according to one aspect of the present disclosure will be described with reference mainly to FIG. 7. FIG. 7 is a flowchart illustrating the substrate processing step according to an aspect of the present disclosure. The substrate processing step according to one aspect of the present disclosure is performed by the above-described substrate processing apparatus 100 as, for example, one step of a manufacturing process of a semiconductor device such as a flash memory. In the following description, the controller 221 controls the operation of each constituent of the substrate processing apparatus 100.

Although not illustrated, a trench having an uneven portion having a high aspect ratio is formed in advance on the surface of the wafer 200 processed in the substrate processing step according to one aspect of the present disclosure. In one aspect of the present disclosure, a layer of, for example, silicon (Si) exposed on an inner wall of the trench is subjected to oxidizing as treatment using plasma.

### (Substrate Loading Step S110)

First, the wafer 200 is loaded into the processing chamber 201. Specifically, the susceptor elevating mechanism 268 lowers the susceptor 217 to a transfer position of the wafer 200, and causes the wafer push-up pins 266 to pass through the through-holes 217a of the susceptor 217. As a result, the wafer push-up pins 266 protrude from the surface of the susceptor 217 by a predetermined height.

Subsequently, the gate valve 244 is opened, and the wafer 200 is loaded into the processing chamber 201 from a vacuum transfer chamber adjacent to the processing chamber 201 by using a wafer transfer mechanism (not illustrated). The loaded wafer 200 is supported in a horizontal posture on the wafer push-up pins 266 protruding from the surface of the susceptor 217. When the wafer 200 is loaded into the processing chamber 201, the wafer transfer mechanism is retracted out of the processing chamber 201, the gate valve 244 is closed, and the processing chamber 201 is sealed. Then, the susceptor elevating mechanism 268 raises the susceptor 217, whereby the wafer 200 is supported on the upper face of the susceptor 217.

### (Temperature Elevation/Vacuum Exhaust Step S120)

Subsequently, the temperature of the wafer 200 loaded into the processing chamber 201 is elevated. The heater 217b is preheated, and the wafer 200 is heated to a predetermined value within a range of 150 to 750° C., for example, by holding the wafer 200 on the susceptor 217 in which the heater 217b is embedded. Furthermore, while the temperature of the wafer 200 is elevated, the inside of the processing chamber 201 is vacuum-exhausted by the vacuum pump 246 via the gas exhaust pipe 231 to set the pressure in the processing chamber 201 to a predetermined value. The vacuum pump 246 is operated until at least substrate unloading step S160 described later is ended.

### (Reactant Gas Supply Step S130)

Next, supply of an oxygen-containing gas and a hydrogen-containing gas as the reactant gases is started. Specifically, the valve 253a and the valve 253b are opened, and the supply of the oxygen-containing gas and the hydrogen-containing gas into the processing chamber 201 is started while the flow rate is controlled by the MFC 252a and the MFC 252b. At this time, the flow rate of the oxygen-containing gas is set to a predetermined value within a range of 20 t0 2000 sccm, for example. The flow rate of the hydrogen-containing gas is set to a predetermined value within a range of 20 to 1000 sccm, for example.

In addition, the degree of opening of the APC valve 242 is adjusted so that the pressure in the processing chamber 201 becomes a predetermined pressure within a range of 1 to 250 Pa, for example, to control exhaust in the processing chamber 201. As described above, while the inside of the processing chamber 201 is appropriately exhausted, the supply of the oxygen-containing gas and the hydrogen-containing gas is continued until the end of plasma processing step S140 described later.

Examples of the oxygen-containing gas may include, but not limited to, an oxygen (O₂) gas, a nitrous oxide (N₂O) gas, a nitrogen monoxide (NO), a nitrogen dioxide (NO₂) gas, an ozone (O₃) gas, a steam (H₂O) gas, a carbon monoxide (CO) gas, and a carbon dioxide (CO₂) gas. One or more of them can be used as the oxygen-containing gas.

As the hydrogen-containing gas, for example, hydrogen (H₂) gas, deuterium (D₂) gas, H₂O gas, ammonia (NH₃) gas, or the like can be used. One or more of them can be used as the hydrogen-containing gas. When H₂O gas is used as the oxygen-containing gas, it is preferable to use a gas other than H₂O gas as the hydrogen-containing gas, and when H₂O gas is used as the hydrogen-containing gas, it is preferable to use a gas other than H₂O gas as the oxygen-containing gas.

As the inert gas, for example, a nitrogen (N₂) gas can be used, and in addition to this, a rare gas such as an argon (Ar) gas, a helium (He) gas, a neon (Ne) gas, or a xenon (Xe) gas can be used. One or more of these gases can be used as the inert gas.

### (Plasma Processing Step S140)

When the pressure in the processing chamber 201 is stabilized, application is started of high-frequency power to the resonance coil 212 from the high-frequency power source 273 via the RF 272.

As a result, a high-frequency electromagnetic field is generated in the plasma generation space to which the oxygen-containing gas and the hydrogen-containing gas are supplied, and the electromagnetic field excites a donut-shaped plasma having the highest plasma density at a height position corresponding to the electrical midpoint of the resonance coil 212 in the plasma generation space. In addition, as described above, by adjusting the coil separation distance at the height position of the lower end of the resonance coil 212, plasma, which is adjusted so that the distribution of the plasma density in the inner circumferential direction of the processing container 203 approaches uniformity, is excited. Although the plasma is excited also at the height position of the upper end of the resonance coil 212, in one aspect of the present disclosure, unlike the lower end side, the distribution of the plasma density in the inner circumferential direction of the processing container 203 is not adjusted by adjusting the coil separation distance. Plasma-like oxygen-containing gas and hydrogen-containing gas dissociate, and reactive species are generated such as oxygen ions and oxygen radicals (oxygen active species) containing oxygen, hydrogen ions and hydrogen radicals (hydrogen active species) containing hydrogen.

On the wafer 200 held on the susceptor 217 in the substrate processing space, radicals generated by the induction plasma and ions in an unaccelerated state are uniformly supplied into a trench. The supplied radicals and ions uniformly react with the side walls to modify the surface layer (for example, Si layer) into an oxide layer (for example, Si oxide layer) with good step coverage.

Thereafter, when a predetermined processing time, for example, 10 to 300 seconds elapses, power output from the high-frequency power source 273 is stopped, and plasma discharge in the processing chamber 201 is stopped. In addition, the valve 253a and the valve 253b are closed to stop the supply of the oxygen-containing gas and the hydrogen-containing gas into the processing chamber 201. Thus, the plasma processing step S140 is ended.

### (Vacuum-Exhaust Step S150)

When the supply of the oxygen-containing gas and the hydrogen-containing gas is stopped, the processing chamber 201 is vacuum-exhausted through the gas exhaust pipe 231. As a result, the oxygen-containing gas and the hydrogen-containing gas in the processing chamber 201, and the exhaust gas generated by the reaction of these gases are exhausted to the outside of the processing chamber 201. Thereafter, the opening degree of the APC valve 242 is adjusted, and the pressure in the processing chamber 201 is adjusted to the same pressure as that of a vacuum transfer chamber (unloading destination of the wafer 200, not illustrated) adjacent to the processing chamber 201.

### (Substrate Unloading Step S160)

When the inside of the processing chamber 201 reaches a predetermined pressure, the susceptor 217 is lowered to the transfer position of the wafer 200, and the wafer 200 is supported on the wafer push-up pins 266. Then, the gate valve 244 is opened, and the wafer 200 is unloaded from the processing chamber 201 by using the wafer transfer mechanism.

Thus, the substrate processing step according to one aspect of the present disclosure is completed.

### (Leak Check)

Leak check of the processing chamber 201 and the seal-related flow path 326 is performed at the time of device start-up before the substrate processing step or at the time of maintenance after the substrate processing step. In the leak check, as a first stage, atmospheric pressure recovery processing is performed in which the inside of the processing chamber 201 is brought into a vacuum state and the seal-related flow path 326 is returned from the vacuum to the atmospheric pressure.

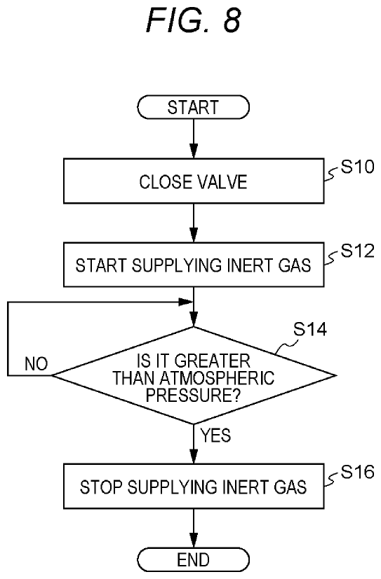

In the atmospheric pressure recovery processing, as shown in FIG. 8, the valve 325 is closed in step S10, and the supply of the inert gas from the second inert gas supply pipe 232d to the seal-related flow path 326 is started in step S12. In step S14, the pressure sensor 324 determines whether the seal-related flow path 326 has reached a predetermined pressure, which is atmospheric pressure herein, or more. When the determination is positive, the gas supply from the second inert gas supply pipe 232d is stopped.

The seal-related flow path 326 is set to the atmospheric pressure and it is confirmed that there is no pressure increase in the processing chamber 201. When it is determined that there is no pressure increase here, it can be confirmed that there is no gas leakage from the first seal portion 270 and the second seal portion 310 to the processing chamber 201.

In the second stage, the valve 253d is closed while the inside of the processing chamber 201 is kept in a vacuum state, and a vacuum pump (not illustrated) is operated to vacuum the seal-related flow path 326. Then, the valve 325 is closed, and the pressure sensor 324 detects the pressure in the seal-related flow path 326. When the pressure detected by the pressure sensor 324 is within a predetermined range, it can be determined that there is no leak.

### (Effects)

According to the present embodiment, one or more effects described below are obtained.

(A) The gap between the flange 210A and the lower lid 211A are sealed by the first seal member 284 and the second seal member 292 disposed farther from the center of the upper container 210 with respect to the first seal member 284. Then, an upper face of the support member 282 provided between the first seal member 284 and the second seal member 292 in the horizontal direction abuts on a lower face of the flange 210A to support the upper container 210. Therefore, as compared with the case where the support member 282 is provided outside the second seal member 292 (on the side opposite to the first seal member 284), the position where the upper container 210 is supported is closer to the center. As a result, even if the side wall of the upper container 210 is pushed inward by the external atmospheric pressure when the inside of the processing chamber 201 is in the vacuum state, the inclination of the side wall is suppressed, and the sealability in the first seal portion 270 can be secured.

(B) The support member 282, the first seal member 284, and the second seal member 292 are set such that a space is secured between the flange 210A (upper container 210) and the lower lid 211A (lower container 211) even when the inside of the processing chamber 201 is brought into a vacuum state in a substrate processing step or the like. Therefore, it is possible to maintain a non-contact state between the upper container 210 and the lower lid 211.

(C) Since the first seal member 284 and the support member 282 are disposed below the flange 210A, the thickness of the peripheral wall 210B of the upper container 210 can be reduced.

(D) Since both the first seal member 284 and the support member 282 are disposed in the upper groove 280A (first groove 280), the size in the radial direction can be reduced as a whole as compared with the case where the grooves are separately formed.

(E) The first groove 280 in which the first seal member 284 and the support member 282 are disposed is provided closer to the center of the upper container 210 than the second groove 290 in which the second seal member 292 is disposed. Therefore, a fulcrum for supporting the upper container 210 by the support member 282 can be brought close to the central side of the upper container 210, and a rotational moment when a force toward the inside of the peripheral wall 210B is applied by a pressure from the outside of the processing chamber can be reduced.

(F) In the first groove 280, the support member 282 is disposed in contact with the first seal member 284. Therefore, movement and torsion of the first seal member 284 can be suppressed.

(G) In the first groove 280, the first seal member 284 and the support member 282 are disposed in the upper groove 280A, and the discharge hole 296A is connected to the lower groove 280B in which these members are not disposed. Therefore, the gas can be smoothly moved in the lower groove 280B, and the retention of the atmosphere can be suppressed.

(H) The first groove 280 is connected to the discharge path 296. Therefore, the gas in the first groove 280 can be easily discharged.

(I) The gap 282A is formed between the support member 282 and a wall of the partition wall 294 constituting the first groove 280. Therefore, the gas retained between the support member 282 and the first seal member 284 can be discharged via the gap 282A.

(J) The support member 282 is divided into a plurality of portions in the circumferential direction in the first groove 280 to form a gap SK, which communicates with the gap 282A. Therefore, the gas retained between the support member 282 and the first seal member 284 can be discharged via the gap SK and the gap 282A which are spaces between the supports 282.

(K) The space in the first groove 280 constitutes a part of the seal-related flow path 326, and communicates with the supply path 297 and the discharge path 296. Therefore, by supplying the inert gas from the supply path 297, the gas in the first groove 280 can be pushed out, and the gas in the first groove 280 can be discharged from the discharge path 296.

(L) In the lower groove 280B, the partition wall 281 is formed, a supply hole 297A communicating with the lower groove 280B is formed on one side across the partition wall 281, and a discharge hole 296A communicating with the lower groove 280B is formed on the other side across the partition wall 281. Therefore, the inert gas can be retained in the first groove 280 to enhance the effect of purging the atmosphere.

(M) The lower groove 280B is formed in a circumferential shape and a partition wall 281 is formed, a supply hole 297A communicating with the lower groove 280B is formed on one side across the partition wall 281, and a discharge hole 296A communicating with the lower groove 280B is formed on the other side across the partition wall 281. Therefore, it is possible to increase the purge effect of the atmosphere by allowing the inert gas to pass circumferentially from one end to the other end in the first groove 280.

(N) The second seal portion 310 is formed in an upper portion of the upper container 210, and a space including the lid groove 314 between the inner seal member 312A and the outer seal member 312B of the second seal portion 310 communicates with the discharge hole 316. The discharge hole 316 is connected to the supply path 297 of the first seal portion 270 via the first intermediate flow path 321. Therefore, the gas in the first seal portion 270 and the second seal portion 310 can be continuously discharged. Therefore, the number of components can be reduced as compared with the case where each component is independent.

(O) The pressure sensor 324 is provided in the second intermediate flow path 322. Before a substrate is processed in the processing chamber 201, the leak check can be performed by detecting a pressure in the seal-related flow path 326 including the intermediate flow path 320 with the pressure sensor 324.

(P) The second intermediate flow path 322 is provided with the pressure sensor 324 and the valve 325. When maintenance is performed after the substrate is processed in the processing chamber 201, the seal-related flow path 326 including the first seal portion 270 and the second seal portion 310 can be returned to the atmospheric pressure by performing the atmospheric pressure recovery processing.

(Q) The gas exhaust pipe 231 provided with the vacuum pump 246 communicates with the processing chamber 201, and a discharge path 296 is connected to a downstream side of the vacuum pump 246 of the gas exhaust pipe 231 via a second intermediate flow path 322. Therefore, the gas in the seal-related flow path 326 can be exhausted without degrading the performance of the vacuum pump 246.

### (3) Modified Example

The first seal portion 270 in the above-described embodiment can be modified as in the following modified example. Configurations in the respective modified examples are similar to those of the embodiment described above unless otherwise specified. In a first seal portion 270-2 which is a modified example of the first seal portion 270, the same reference numerals are given to the same portions as those of the above-described embodiment, and the detailed description thereof will be omitted.

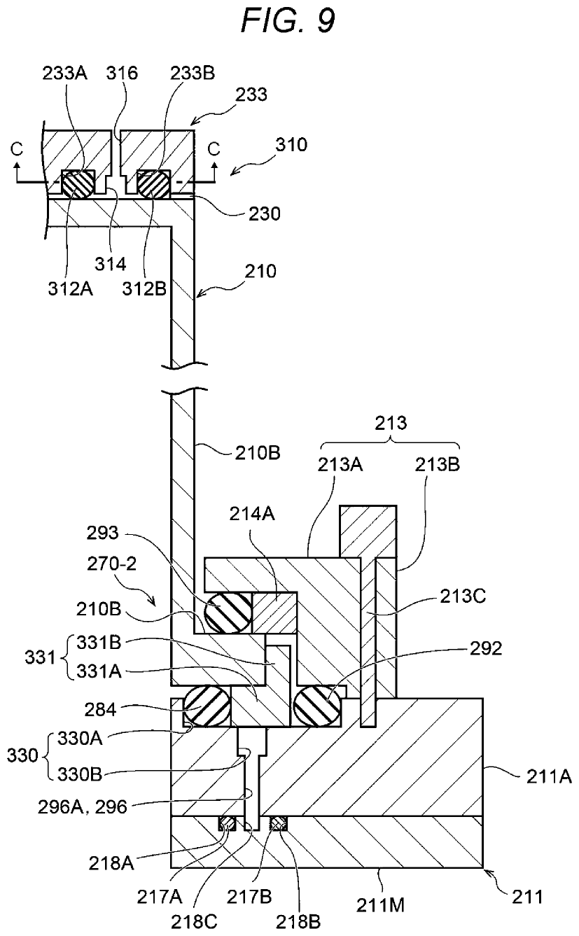

In the modified example, as illustrated in FIG. 9, the support member 331 has an L-shaped cross section facing radially inward, and includes a lower support portion 331A and an outer support portion 331B. The support member 331 has a ring shape. The lower support portion 331A is in contact with the lower face of the flange 210A and supports the flange 210A. The outer support portion 331B is in contact with the outer peripheral end surface of the flange 210A.

The flange retainer 213 is externally fitted to the flange 210A, and the third seal member 293 is disposed between the upper surface of the flange 210A and the retaining portion 213A. On the lower face of the retaining portion 213A, a cushion material 214 is provided outside the alarm section of the third seal member 293, and the flange 210A abuts on the flange retainer 213 via the cushion material 214. The second seal member 292 is disposed on the radially inner lower face of the side portion 213B.

A groove 330 is formed on the radially inner side of the upper face of the lower lid 211A. The groove 330 is formed in an annular shape and includes an upper groove 330A and a lower groove 330B. The upper groove 330A is disposed on the upper face side of the lower lid 211A, and the lower groove 330B is narrower than the upper groove 330A and is formed with a step below the upper groove 330A. In the lower groove 330B, a partition wall is formed similarly to the partition wall 281 formed in the lower groove 280B described above. The supply path 297 and the discharge path 296 are connected to the lower groove 330B.

This modified example is suitable when the radial length of the flange 210A is relatively short.

### <Other Aspects>

Various exemplary embodiments and modified examples of the present disclosure have been described above, but the present disclosure is not limited to such embodiments. Thus, any appropriate combination thereof can be provided.

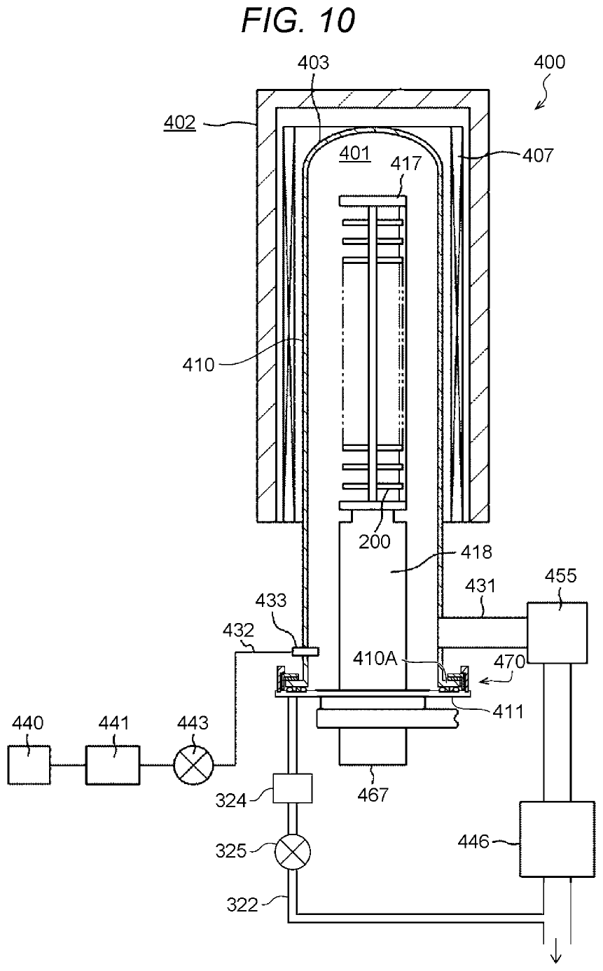

For example, in the above embodiment, a single wafer type apparatus that processes substrates one by one has been described, but the present disclosure can also be applied to a vertical substrate processing apparatus 400 illustrated in FIG. 10. The substrate processing apparatus 400 includes a processing furnace 402 that processes the wafer 200. The processing furnace 402 is provided with a processing container 403 including a processing chamber 401. The processing container 403 is provided inside the heating device 407. The processing container 403 includes a cylindrical upper container 410 and a lower container 411 that covers a lower opening of the upper container 410. When the upper container 410 covers the lower container 411, the processing chamber 401 is formed between the upper container 410 and the lower container 411.

A boat 417 for placing a plurality of wafers 200 in multiple stages at the same interval is provided in a central portion in the processing container 403. The boat 417 is a substrate holder that holds the wafers 200 in a horizontal posture in multiple stages. The boat 417 is supported on an upper portion of the lower container 411 via a quartz cap 418.

The boat 417 can move into and out of the processing container 403 by lifting and lowering by a boat elevator (not illustrated). In addition, a boat rotating mechanism 467 for rotating the boat 417 is provided in order to improve uniformity of processing, and the boat 417 held by the quartz cap 418 is rotated by the boat rotating mechanism 467.

Gas supply in the substrate processing apparatus 400 can include a processing gas supply source 440, a mass flow controller 441, and a valve 443 provided in the processing gas supply pipe 232. In addition, as an exhaust system for exhausting gas from the processing chamber 401, a gas exhaust pipe 431, an APC valve 455, and a vacuum pump 446 can be configured.

A flange 410A is formed at a lower end of the upper container 410, and a first seal portion 470 is formed at a boundary portion between the flange 410A and the lower container 411. The first seal portion 470 can have the same configuration as the first seal portion 270 described above. The second intermediate flow path 322 for discharging the gas from the first seal portion 470 is connected to the gas exhaust pipe 431 on the downstream side of the vacuum pump 446.

The support members, the seal portions, the seal members in the above-described embodiment and modification are examples of a support, a sealer, and a packing, respectively.

Note that particular embodiments and modified examples of the present disclosure have been described in detail, but the present disclosure is not limited to such embodiments and modified examples. Thus, it is obvious to those skilled in the art that other various embodiments can be made without departing from the scope of the present disclosure.

According to the present disclosure, it is possible to suppress penetration of external gas into the processing chamber.

What is claimed is:

1. A substrate processing apparatus comprising:
an upper container;
a lower container provided below the upper container and constituting a processing chamber between the lower container and the upper container;
a first sealer disposed in a boundary region between the upper container and the lower container, the first sealer including a first packing and a second packing; and
a support that includes a support face disposed at a highest position below the upper container, is provided between the first packing and the second packing in a horizontal direction, and is made of a material harder than the first packing and the second packing.

2. The substrate processing apparatus according to claim 1, wherein the support is configured such that, when a substrate is processed, in a state where a pressure in the processing chamber is lower than a pressure outside the processing chamber, a space between the lower container and the upper container can be secured without contact between the lower container and the upper container.

3. The substrate processing apparatus according to claim 1, wherein:
a side wall of the upper container includes a peripheral wall extending at least in a vertical direction and a flange extending in a horizontal direction from the peripheral wall; and
at least a part of the first packing and the support and the support face are disposed below the flange.

4. The substrate processing apparatus according to claim 1, wherein the lower container is provided with a first groove in which the first packing and the support are disposed.

5. The substrate processing apparatus according to claim 4, wherein the lower container is provided with a second groove in which the second packing is disposed, and the first groove is provided on a central side of the upper container with respect to the second groove.

6. The substrate processing apparatus according to claim 4, wherein in the first groove, the first packing is disposed on the central side of the upper container with respect to the support, and the support is disposed in contact with the first packing.

7. The substrate processing apparatus according to claim 4, wherein:
the first groove includes an upper groove and a lower groove;
the first packing and the support are disposed in the upper groove; and
a discharge hole is provided in the lower groove.

8. The substrate processing apparatus according to claim 4 further comprising a discharge path communicating with a space in the first groove.

9. The substrate processing apparatus according to claim 4, wherein:
a discharge path communicating with a space in the first groove is provided; and
in the first groove,
the first packing is disposed on the central side of the upper container with respect to the support,
the support is disposed in contact with the first packing, and
a gap is provided between a wall on a side opposite to a central side of the upper container among walls constituting the first groove and the support.

10. The substrate processing apparatus according to claim 4, wherein:
a discharge path communicating with a space in the first groove is provided; and
in the first groove,
the first packing is disposed on the central side of the upper container with respect to the support,
the support is arranged in a state of being divided into a plurality of parts and is arranged in a state of being in contact with the first packing, and
a gap is provided between the support and a wall constituting the first groove on a side opposite to the central side of the upper container among walls constituting the first groove, and the gap is configured to communicate with a space between the respective supports.

11. The substrate processing apparatus according to claim 4, wherein a space in the first groove is configured to communicate with a supply path and/or a discharge path.

12. The substrate processing apparatus according to claim 9, wherein:
a supply hole communicating with a supply path and a discharge hole communicating with the discharge path are provided in the first groove; and
a wall is provided between the supply hole and the discharge hole in the first groove.

13. The substrate processing apparatus according to claim 9, wherein:
a supply hole communicating with a supply path and a discharge hole communicating with the discharge path are provided in the first groove;
the first groove is provided in a circumferential shape; and
a wall is provided between the supply hole and the discharge hole.

14. The substrate processing apparatus according to claim 11, wherein:
a lid and a second sealer disposed between the upper container and the lid are provided above the upper container; and
the substrate processing apparatus further comprises a second discharge path provided in the second sealer, and an intermediate flow path that allows the supply path and the second discharge path to communicate with each other.

15. The substrate processing apparatus according to claim 14, wherein:
a pressure sensor is provided in the intermediate flow path; and
the pressure sensor is configured to detect a pressure in the intermediate flow path before processing a substrate in the processing chamber.

16. The substrate processing apparatus according to claim 14, wherein:
a pressure sensor and a valve are provided in the intermediate flow path; and
when maintenance is performed after a substrate is processed in a processing chamber including the upper container and the lower container,
an inert gas is supplied to the intermediate flow path in a state where the valve is closed, and the pressure sensor is configured to stop the supply of the inert gas when a pressure in the intermediate flow path becomes a predetermined value or more.

17. The substrate processing apparatus according to claim 14, wherein:
an exhaust pipe provided with a pump communicates with the processing chamber; and
the discharge path communicates with a downstream side of the pump in the exhaust pipe.

18. A substrate processing method for processing a substrate in a processing chamber of a substrate processing apparatus comprising:
an upper container;
a lower container provided below the upper container and constituting the processing chamber between the lower container and the upper container;
a first sealer disposed in a boundary region between the upper container and the lower container, the first sealer including a first packing and a second packing; and
a support that includes a support face disposed at a highest position below the upper container, is provided between the first packing and the second packing in a horizontal direction, and is made of a material harder than the first packing and the second packing.

19. A method of manufacturing a semiconductor device, the method comprising the substrate processing method according to claim 18.

20. A computer-readable recording medium storing a program that a computer causes a substrate processing apparatus to execute for processing a substrate in a processing chamber of the substrate processing apparatus comprising:
an upper container;
a lower container provided below the upper container and constituting the processing chamber between the lower container and the upper container;
a first sealer disposed in a boundary region between the upper container and the lower container, the first sealer including a first packing and a second packing; and
a support that includes a support face disposed at a highest position below the upper container, is provided between the first packing and the second packing in a horizontal direction, and is made of a material harder than the first packing and the second packing.
